(19) United States
(12) Patent Application Publication
(10) Pub. No.: US 2006/0097733 A1
(43) Pub. Date: May 11, 2006

(54) System and method for capacitive measuring

(76) Inventor: Didier Roziere, Nimes (FR)

Correspondence Address: YOUNG & THOMPSON, 745 SOUTH 23RD STREET, 2ND FLOOR, ARLINGTON, VA, 22202, US

(21) Appl. No.: 10/525,775

(22) PCT Filed: Aug. 27, 2003
(86) PCT No.: PCT/FR03/02587

§ 371 Date: Sep. 29, 2005

(30) Foreign Application Priority Data
Aug. 30, 2002 (FR) 02/10754

(51) Int. Cl. G01R 27/26

(52) U.S. Cl. 324/662

(57) ABSTRACT

A system (S′) for non-contact measurement of a relative displacement or relative position of a first object relative to a second object, has: a sensor module including a transmitter plate fixed to the first object and a receiver plate connected to the second object, arranged substantially facing each other and provided with respectively transmitting and receiving electrodes; and an electronic module designed to apply on the transmitting electrodes high-frequency excitation signals, and to process measurement signals derived from the receiving electrodes. The transmitting and receiving electrodes are designed to constitute a first variable capacitance based on the relative misalignment of the plates. The electronic module is designed to perform an analog calculation of a first signal representing the inverted capacitance and of a second signal representing the ratio of the second capacitance over the first capacitance. The invention is in particular useful for controlling segmented mirrors in large telescopes.

The present invention relates to a system for non-contact measurement of a relative displacement or positioning of two adjacent objects by capacitive means. It also relates to the non-contact measurement method used in this system and to the application of this system to the control of mirrors, in particular to segmented mirrors.

The principal but non-limitative field of application of the present invention is that of giant telescopes with segmented mirrors in which it is necessary to control the Tip, Tilt and Piston devices of the segmented mirrors with high resolution and the Global Radius of Curvature of the mirror, referred to by the term GROC.

The publication “Segmented Mirror Control System Hardware for CELT” by Terry S. Mast and Jerry E. Nelson published in the proceedings of SPIE 2000 thus discloses a control system for segmented mirrors using capacitive displacement sensors for the three-dimensional control of the mirror segments.

The use of capacitive technology edge sensors arranged on the lateral edges of mirror segments is also known.

Furthermore, there are also non-contact systems for measuring the relative positions of conductive copper tracks on smart cards during machining, which use a calculation of the type (CA−CB)/(CA+CB), where CA and CB represent capacitances constituted by two transmitting electrodes and two receiving electrodes in a situation of relative misalignment.

The purpose of the present invention is to propose a non-contact measurement system using capacitive means which has better performance with respect to measurement precision than current capacitive measurement systems, whilst allowing a reduction in production costs.

This objective is achieved with a system for non-contact measurement of a relative displacement or of a relative position of a first object with respect to a second object, comprising:
a sensor module comprising a transmitting plate fixed to said first object and a receiving plate connected to said second object, said first transmitting plates and said second receiving plate being arranged substantially facing each other and provided with transmitting and receiving electrodes respectively,
means of applying high-frequency excitation signals to said transmitting electrodes,
means of taking high-frequency modulated measurement signals from said receiving electrodes, and
means of processing said measurement signals thus taken in order to supply signals representing the relative displacement or the relative position of said first object with respect to said second object.

According to the invention, the transmitting and receiving electrodes are arranged to constitute a first capacitance varying as a function of the distance separating the transmitting and receiving plates respectively and a second capacitance varying as a function of the relative misalignment of said plates, and the processing means are designed to perform, on the basis of the measurement signals taken, an analogue calculation (i) of a first signal representing the inverse of said first capacitance and (ii) of a second signal representing the ratio of the second capacitance to said first capacitance.

With the non-contact measurement system according to the invention, it is thus possible to provide simultaneously both information representing the relative separation of two objects, for example segmented mirrors, and information representing the misalignment of these two objects, with very high precision made possible by an analogue calculation performed on capacitive measurement signals.

In order to maintain high performance levels, the analogue computer is preferably produced with one or more modulators.

In an advantageous embodiment, the transmitting electrodes comprise at least a first transmitting electrode (T1) with a first polarity, a second transmitting electrode (TA) with said first polarity and

a transmitting electrode (TB) with a second polarity that is the inverse of said first polarity, the receiving electrodes comprising at least a first receiving electrode (R1) substantially facing said first transmitting electrode (T1) and a second receiving electrode (R(A−B)) substantially facing a part of said second transmitting electrode (TA) and a part of said transmitting electrode (TB) of inverse polarity.

The transmitting electrodes can for example comprise two first transmitting electrodes (T1, T2) with the first polarity exhibiting substantially the same first geometric shape, and the receiving electrodes comprise two first receiving electrodes (R1, R2) exhibiting the first geometric shape and arranged within the receiving plate in order to be respectively facing said first transmitting electrodes when said transmitting and receiving plates are in alignment.

The second transmitting electrode (TA) and the transmitting electrode of inverse polarity (TB) exhibit the same second geometric shape, for example rectangular, and are arranged parallel and in close proximity to each other.

The second receiving electrode (R(A−B)) is preferably arranged within the receiving plate such that the projection of said second receiving electrode on the transmitting plate is included within a perimeter including the contours of the second transmitting electrode (TA) and of the receiving electrode of inverse polarity (TB).

The two first transmitting electrodes (T1, T2) and the second transmitting electrode (TA) can be electrically connected and excited by a same high-frequency modulated excitation signal and the two first receiving electrodes (R1, R2) are electrically connected.

The processing means can advantageously comprise means for performing the analogue calculation:
1/(C1+C2)
where C1 and C2 are the capacitances respectively constituted by the first transmitting electrodes (T1, T2) and the first receiving electrodes (R1, R2) and means of performing the analogue calculation:
CA−CB/(C1+C2)
where C1 and C2 are the capacitances respectively constituted by the first transmitting electrodes (T1, T2) and the first receiving electrodes (R1, R2) and where CA−CB represents the capacitance constituted by, on the one hand, the second transmitting electrode (TA) and the transmitting electrode of inverse polarity (TB) and, on the other hand, the second receiving electrode (R(A−B)).

The differential measurement CA−CB can be carried out either with a bi-electrode transmitter and a mono-electrode receiver or with a mono-electrode transmitter and a bi-electrode receiver.

The capacitances C1 and C2 make it possible to avoid the use of two charge amplifiers which would considerably degrade the thermal drift of the electronics.

The separate measurements of (CA−CB)/(C1+C2) and 1/(C1+C2) thus make it possible to carry out radial and axial measurements.

The processing means preferably comprise a preamplifier stage (20) for pre-amplifying the measurement signals respectively taken from the second receiving electrode (R(A−B)) and from the two first, electrically connected, receiving electrodes (R1, R2), upstream of the analogue calculating means (21).

According to another aspect of the invention, an application of the system for non-contact measurement according to the invention for measuring the relative position between two adjacent mirror segments is proposed. In this application, the transmitting and receiving plates respectively are fixed to facing lateral edges of two adjacent mirrors, in close proximity to the active surfaces of said mirror segments.

According to yet another aspect of the invention, there is proposed a method for non-contact measurement of a relative displacement or of a relative position of a first object with respect to a second object, used in a system according to the invention, comprising:
an application of high-frequency excitation signals to transmitting electrodes arranged on a transmitting plate fixed to said first object,
a taking of high-frequency modulated measurement signals from receiving electrodes arranged on a receiving plate fixed to said second object, at least a part of said electrodes, transmitting and receiving respectively, being substantially facing each other when the transmitting and receiving plates respectively are substantially aligned,
a processing of said measurement signals thus taken in such a way as to provide signals representing the relative displacement or the relative position of said first object with respect to said second object,
   characterized in that this processing comprises an analogue calculation (i) of a first signal representing the inverse of a first capacitance and (ii) of a second signal representing the ratio of a second capacitance to said first capacitance, said first capacitance being constituted by at least one of said transmitting electrodes and at least one of said receiving electrodes in such a way as to vary as a function of the distance separating the transmitting and receiving plates respectively and said second capacitance being constituted by at least one other of said transmitting electrodes and at least one other of said receiving electrodes in such a way as to vary as a function of the relative misalignment of said plates.

Other advantages and features of the invention will appear on examining the detailed description of one embodiment, that is in no way limitative, and the attached drawings in which:

FIG. 1 is a diagrammatic representation of the transmitting and receiving plates respectively used in a measurement system according to the invention;

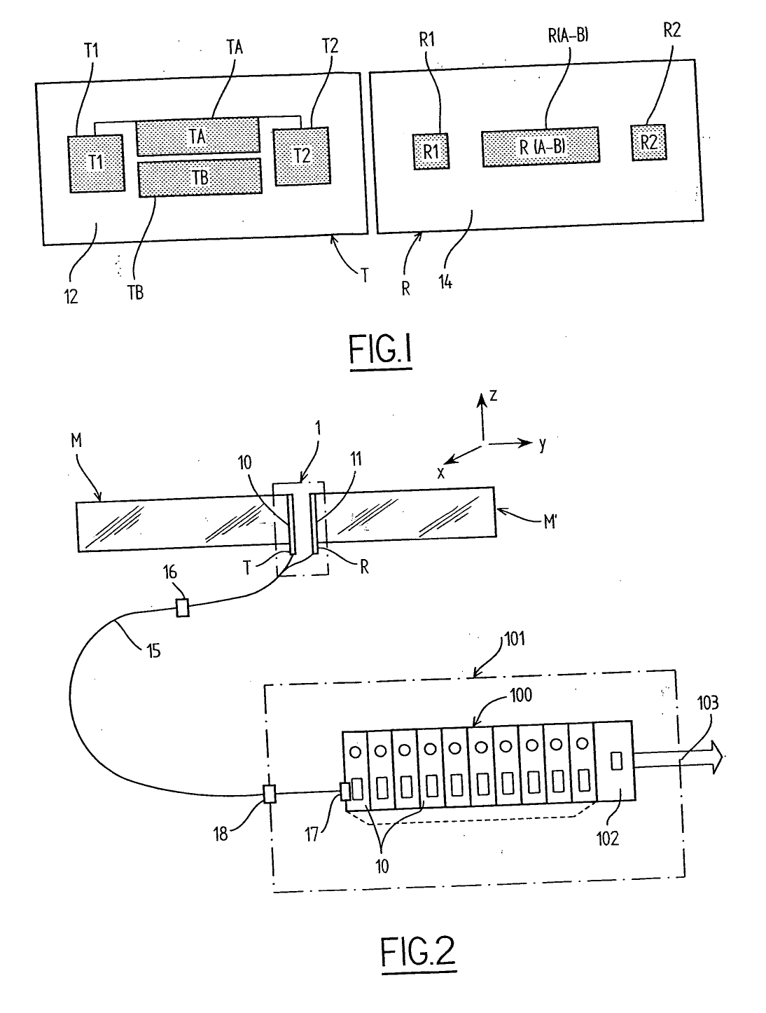

FIG. 2 illustrates a practical implementation of a measurement system according to the invention;

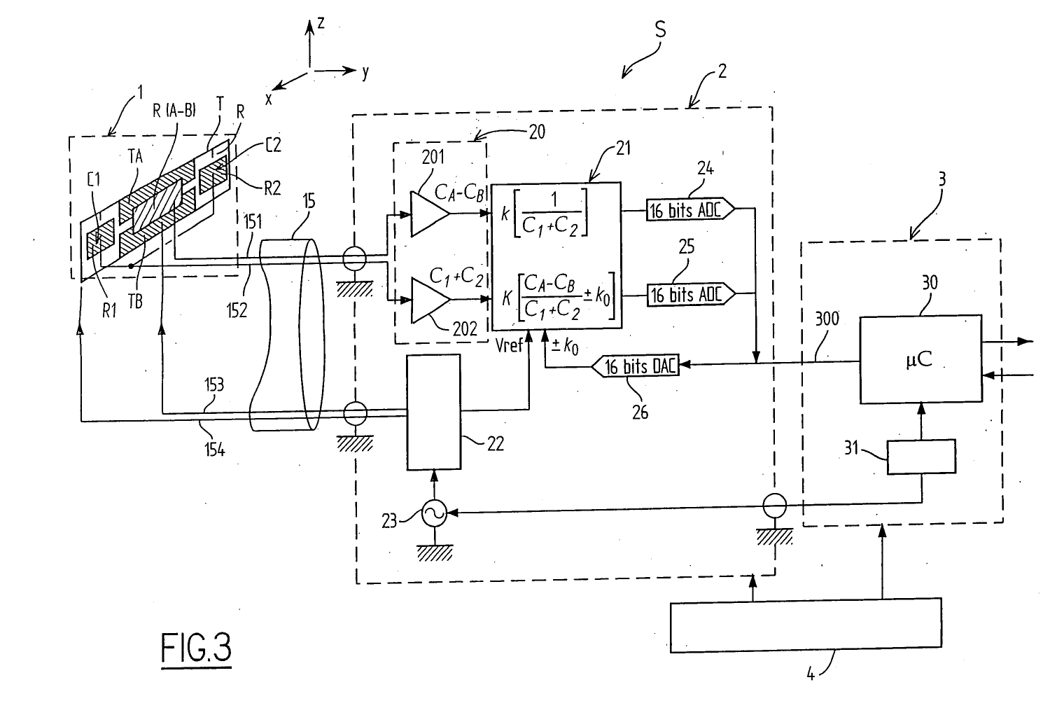

FIG. 3 illustrates a diagrammatic representation of a first example embodiment of the internal structure of a measurement system according to the invention;

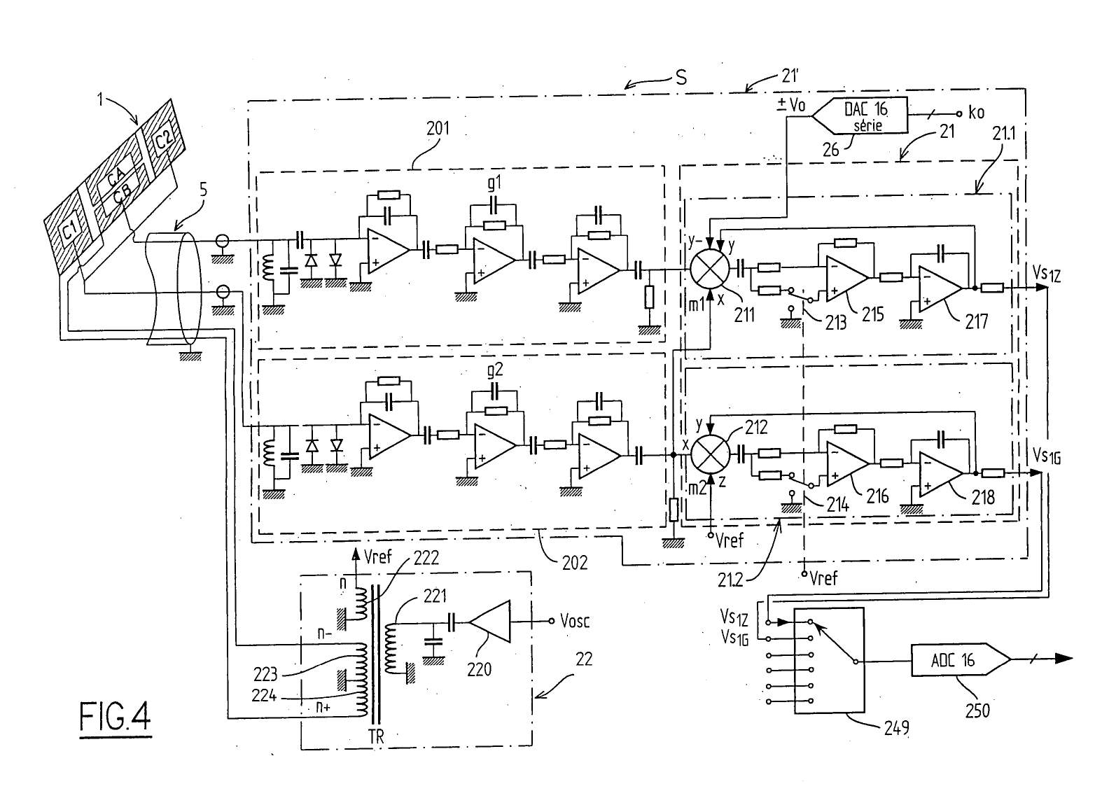

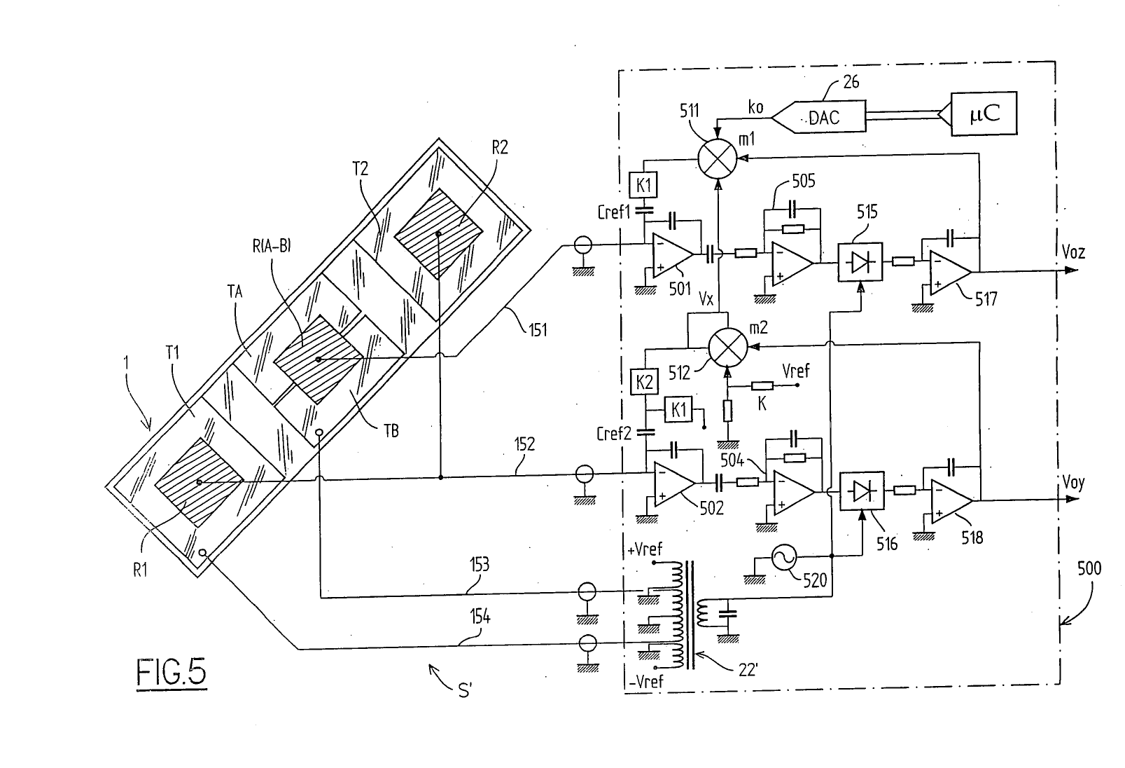

FIG. 4 illustrates a practical example of embodiment of the measurement system shown in FIG. 3; and

FIG. 5 illustrates a second example embodiment of a measurement system according to the invention.

There will firstly be described, with reference to FIGS. 1 and 2, an example embodiment of a sensor module used in a non-contact measurement system according to the invention used for controlling a set of segmented mirrors. This sensor module 1, arranged between two mirror segments M, M′ comprises a transmitting plate T fixed to a lateral edge 10 of the segment M and a receiving plate R fixed to a lateral edge 11 of the segment M′, these two plates, transmitting T and receiving R respectively, being substantially facing and parallel with each other.

The transmitting plate T comprises, on a thin flat support 12 made of insulating material, two, first and second, transmitting electrodes T1, T2 of positive polarity, square shaped and electrically connected to a third transmitting electrode TA of positive polarity and of rectangular shape arranged between the first and second transmitting electrodes. The transmitting plate T furthermore comprises a transmitting electrode TB of negative polarity whose shape is identical to that of the third transmitting electrode TA and arranged parallel with the latter.

The receiving plate R comprises, on a thin flat support 14 made of insulating material, two square-shaped, first and second, receiving electrodes R1, R2 and a third receiving electrode R(A−B) of rectangular shape arranged between the two, first and second, receiving electrodes R1, R2. The surface of the supports 12, 14 not occupied by said electrodes is metallized and forms an electrostatic shield for these electrodes.

By way of non-limitative example, the supports 12, 14 can be made of hard material, which makes it possible to obtain the required dimensional stability, and are coated with gold.

The supports can also be made of flexible material, such as polyimide, glued onto the mirror. The gluing, with a thin resin, makes it possible to greatly reduce the coefficient of thermal expansion of the sensor and to improve the dimensional stability of the flexible material supporting the sensor, due to the low coefficient of thermal expansion of the mirror. The flexible material can be produced with conventional flexible printed circuit.

As the two plates, transmitting T and receiving R respectively, are arranged in a parallel manner and separated by a distance, in practice of a few mm up to a few cm, there is therefore obtained a first capacitance C1 constituted by the first transmitting electrode T1 and the first receiving electrode R1, a second capacitance C2 constituted by the second transmitting electrode T2 and the second receiving electrode R2, and a subtractive capacitive device CA−CB constituted, on the one hand, by the third positive rectangular transmitting electrode TA and the negative transmitting electrode TB and, on the other hand, the third receiving electrode R(A−B).

The sensor module 1 is connected by one or more screened cables 15 to an electronic processing module 10 installed in a rack 100 in the standard 3U format which can contain several electronic processing modules and is arranged within a container 101. The screened cable 15 is connected, on the one hand, to electrical conductors connected to the sensor module 1 by means of a first connector 16 and, on the other hand, to the container 101 by means of a second connector 18 and then to the electronic equipment 10 by means of a third connector 17. The rack 100 also includes a multi-channel acquisition module connected to the different electronic processing modules 10 and to an external interface bus 103.

The arrangement of the sensor module 1 between two mirror segments allows quality measurement since it is very close to the optical surfaces. Furthermore, because of the remote nature of the electronic processing modules, there is no heat dissipation in the vicinity of the mirror segments.

There will now be described, with reference to FIG. 3, a first example of embodiment of an electronic processing module 2 connected on the one hand to the sensor module 1 via the screened cable 15 and, on the other hand, to a digital acquisition card 3 provided with a microcontroller 30 and a clock 31.

The electronic processing module 2 comprises a first preamplification stage 20 including a first preamplifier 201 and a second ultra low noise preamplifier 202 receiving as inputs a signal taken from the receiving electrode R(A−B) and a signal taken from the two receiving electrodes R1 and R2 connected in parallel respectively. This first preamplification stage 20 has its output connected to an analogue computer 21 whose two output signals are applied as inputs to two 16-bit analogue-to-digital converters 24, 25 providing digital data routed to the microcontroller 30 via an internal bus 300.

The electronic processing module 2 furthermore comprises a high-stability differential amplifier 22 provided for supplying an excitation signal for the three positive transmitting electrodes T1,T2,TA and an excitation signal to the negative transmitting electrode TB. This differential amplifier 22 receives a reference signal supplied by a reference oscillator 23 controlled by a clock signal generated by the clock circuit 31, and also provides a modulation reference signal applied as an input to the analogue computer 21 which also receives an offset control signal representing an analogue coefficient ko supplied by a digital-to-analogue converter connected to the digital bus 300. Furthermore, the analogue processing module 2 is electrically powered by an electrical power supply module 4 also provided for powering the digital card 3.

The two excitation signals supplied by the differential amplifier 22 are respectively transmitted to the set of positive transmitting electrodes T1, T2, TA and to the negative transmitting electrode TB via two wired connections, 154 and 153 respectively, included in the screened cable 15, whilst the two reception signals taken from the differential receiving electrode R(A−B) and from the two receiving electrodes RA, RB respectively are applied as inputs to the preamplification stage 20 via two wired connections 151 and 152 respectively.

The first preamplifier 201 is provided for supplying a signal representing the difference CA−CB, whilst the second preamplifier 202 is provided for supplying a signal representing the sum C1+C2. These two analogue signals are applied as inputs to the analogue computer 21 which is arranged to generate two analogue signals respectively representing the quantity

$$k [ \frac{1}{C1 + C2} ]$$

and the quantity

$$K [ \frac{CA - CB}{C1 + C2} \pm k0 ] .$$

FIG. 4 illustrates a practical example of embodiment of an electronic processing module 21′. The low-noise preamplifiers 201, 202 are connected according to a conventional structure based on operational amplifiers. The differential amplifier 22 comprises a transformer TR comprising a primary winding 221 connected to the output of an amplifier 220 to which is applied an oscillation reference signal Vosc, a first secondary winding 222 provided for supplying a reference voltage Vref used by the analogue computer 21, and two secondary windings 223, 224 with a common centre point provided for supplying the respective excitation signals for all of the positive transmitting electrodes T1, T2, TA and for the negative transmitting electrode TB.

The analogue computer 21 comprises a first calculation module 21.1 including a mixer circuit 211 receiving on input the signal supplied by the first preamplification stage 201 and representing the quantity CA−CB, the signal supplied by the second preamplification stage 202 and representing the quantity C1+C2, an offset signal supplied by the digital-to-analogue converter 26 and the output signal Vs1z of this first calculation module, and supplying a signal applied as a negative input of a differential amplifier stage 215 whose positive input is connected to a first switch 213 between the output signal of the mixer 211 and earth, this first switch 213 being controlled by the reference voltage Vref.

A second calculation module 21.2 includes a mixer circuit 212 receiving as input the signal supplied by the second preamplifier 202, the reference voltage Vref, and the output signal Vs1G of this second calculation module, and supplying a signal which is applied as the negative input of a differential amplifier stage 216 whose positive input is connected to a second switch 214 between the output signal of the mixer 212 and earth, this second switch 214 also being controlled by the reference voltage Vref.

The respective outputs of the two differential amplifiers 215, 216 are applied as inputs to two demodulator integrator circuits 217, 218 in order to provide the output signals Vs1z, Vs1G of the analogue computer 21. These two output signals are applied as inputs to a multiplexer 249 whose analogue output is applied as input to an analogue-to-digital converter 250 generating digital data intended to be processed by the microcontroller 30 of the digital card 3 of the non-contact measurement system according to the invention.

It is possible to establish that the output signal Vs1z represents the ratio

$$\frac{n + . CA - n - . CB}{C1 + C2}$$

where n− and n+ are the respective number of turns of the secondary windings 223, 224 connected to the negative transmitting electrode TB and to all of the positive transmitting electrodes T1, T2, TA respectively.

A second example of embodiment of a measurement system according to the invention will now be described with reference to FIG. 5. The components and elements of the first and second examples of embodiment common to FIGS. 3 to 5 are indicated by common references.

This measurement system S′ comprises a sensor module 1 of the type described above and an electronic processing module 500 which uses conventional bridges controlled by means of modulators at the input of charge amplifiers.

The positive transmitting electrodes T1, T2, TA and the negative transmitting electrode TB are fed with high-frequency excitation signals by the feed module 22′ controlled by the output signal of the oscillator circuit 520.

The third receiving electrode R(A−B) is connected via a conductor 151 to the input of a first charge amplifier 501, whilst the first and second receiving electrodes R1, R2 are connected via a conductor 152 to the input of a second charge amplifier 502.

A first modulator 511, connected as a multiplier, receives as input: a first output signal Voz of the processing module 500, an analogue signal ko generated by a digital-to-analogue converter (DAC) 26 controlled by a microcontroller (μC), and an analogue signal Vx produced internally by the processing module 500. This first modulator 511, which is associated with a first modulation coefficient m1, supplies an output modulation signal which is applied via a gain K1 and a first reference capacitor Cref1 as an input to the first charge amplifier 501.

A second modulator 512, connected as a divider, with which is associated a second modulation coefficient m2, receives as input: a reference signal Vref, to which a multiplicative coefficient K is applied, and a second output signal Voy of the processing module 500. This second modulator 512 supplies a modulation output signal Vx which is applied, via a gain K2 and a second reference capacitor Cref2, as an input to the second charge amplifier 502.

The reference outputs +Vref and −Vref of the feed module 22′ are used for controlling the first and second modulators 511, 512.

The output signal of the first charge amplifier 501 is applied as input to a first high-frequency amplifier 505 whose output is applied as input to a first synchronous demodulator 515. The output signal of this first synchronous demodulator is applied as input to an integrator 517 which supplies the first output signal Voz representing a displacement along the z axis.

The output signal of the second charge amplifier 502 is applied as input to a second high-frequency amplifier 504 whose output is applied as input to a second synchronous demodulator 516 generating a demodulated signal which is applied as input to a second integrator 518 supplying the second output signal Voy.

The two, first and second, synchronous demodulators 515, 516 are controlled by the oscillator circuit 520.

The use of a real zero method measurement for the electronic processing module 500 procures a decisive advantage in terms of resolution performance. This is made possible by the use of a divider modulator and a multiplier modulator and by the fact that the voltage signal Vx is injected into the multiplier module 511.

The output signals Voz and Voy can be expressed as follows:

$$Voz = \frac{1}{{m}_{2}} [ \frac{{n}^{+} Ca - {n}^{-} Cb}{{n}^{+} ( {C}_{1} + {C}_{2} ) - {C}_{1} \cdot {K}_{1}} * \frac{{K}_{2} \cdot {Cref}_{2}}{{K}_{1} \cdot {Cref}_{1}} ] \pm k0$$

$$Voy = \frac{K \cdot {K}_{2} {Cref}_{2} \cdot {m}_{2}}{{n}^{+} ( {C}_{1} + {C}_{2} ) - {C}_{1} {K}_{1}}$$

In the practical example of embodiment of a measurement system according to the invention, the sensor module inserted between the mirror segments has the following dimensional and electrical characteristics:

| Transmitting plate: | | |
|---|---|---|
| Area of the electrodes TA and TB: | 20 × 40 | mm² |
| Area of the electrodes T1 and T2: | 40 × 40 | mm² |
| Area of the transmitting plate: | 50 × 130 | mm² |
| Receiving plate: | | |
| Area of the electrode R(A-B): | 20 × 30 | mm² |
| Area of the electrodes R1 and R2: | 20 × 20 | mm² |
| Area of the receiving plate: | 50 × 130 | mm² |
| Inter-plate distance: | between 6 and 18 | mm |
| Capacitance (for an | | |
| inter-plate distance of 17 mm): | | |
| CA = CB = 0.15 pF | | |
| C1 = C2 = 0.20 pF | | |
| Sensitivity along z axis: | 30 | pF/m |
| Sensitivity along Y axis: | 11 | pF/m |

In a practical example of embodiment of an electronic equipment associated with the sensor module described above:

| | | |
|---|---|---|
| Electronic measurement noise on Z axis: | 10 | nm/Hz^{1/2} |
| Electronic measurement noise on Y axis: | 20 | nm/Hz^{1/2} |
| Z axis range: | +/−0.5 | mm |
| Y axis range: | 6-18 | mm |
| Offset adjustment: | +/−0.5 | mm |
| Z axis output signal: | +/−10 | V |
| Y axis output signal | 0-10 | V |
| Output resolution: | 15 | nm |
| (analogue-to digital conversion | | |
| in 16 bits on Z axis) | | |
| Pass band | 0-10 | Hz |
| Gain and offset drift: | <10 | nm/° C. |
| Offset control resolution: | 15 | nm |
| (analogue-to digital conversion | | |
| in 16 bits on Z axis) | | |
| Serial interface | | |
| Electrical power supply: | 120 or 230 | V |
| 8-channel 3U 19-inch format rack | 15 | m |
| Length of sensor-electronics cable: | | |

The invention is not of course limited to the examples that have just been described and numerous modifications can be applied to these examples without departing from the scope of the invention. The measurement system according to the invention can, in particular, be used for controlling segmented primary mirrors and for adaptive optics and also for controlling secondary mirrors.

1. System (S, S′) for non-contact measurement of a relative displacement or of a relative position of a first object with respect to a second object, comprising:
a sensor module (1) comprising a transmitting plate (T) fixed to said first object and a receiving plate (R) connected to said second object, said first transmitting plates and said second receiving plate being arranged substantially facing each other and provided with transmitting and receiving electrodes respectively,
means (22) of applying high-frequency excitation signals to said transmitting electrodes,
means of taking high-frequency modulated measurement signals from said receiving electrodes, and
means (2,500) of processing said measurement signals thus taken in order to supply signals representing the relative displacement or the relative position of said first object with respect to said second object,
characterized in that the transmitting and receiving electrodes are arranged to constitute a first capacitance varying as a function of the distance separating the transmitting and receiving plates respectively and a second capacitance varying as a function of the relative misalignment of said plates, and in that the processing means are designed to perform, on the basis of the measurement signals taken, an analogue calculation (i) of a first signal representing the inverse of said first capacitance and (ii) of a second signal representing the ratio of the second capacitance to said first capacitance.

2. System (S, S′) for non-contact measurement according to claim 1, characterized in that the transmitting electrodes comprise at least a first transmitting electrode (T1) with a first polarity, a second transmitting electrode (TA) with said first polarity and a transmitting electrode (TB) with a second polarity that is the inverse of said first polarity, the receiving electrodes comprising at least a first receiving electrode (R1) substantially facing said first transmitting electrode (T1) and a second receiving electrode (R(A−B)) substantially facing a part of said second transmitting electrode (TA) and a part of said transmitting electrode (TB) of inverse polarity.

3. System for measurement according to claim 2, characterized in that the transmitting electrodes comprise two first transmitting electrodes (T1, T2) with the first polarity exhibiting substantially the same first geometric shape, and in that the receiving electrodes comprise two first receiving electrodes (R1, R2) exhibiting said first geometric shape and arranged within the receiving plate in order to be respectively facing said first transmitting electrodes when said transmitting and receiving plates are in alignment.

4. System for measurement according to claim 2, characterized in that the second transmitting electrode (TA) and the transmitting electrode of inverse polarity (TB) exhibit the same second geometric shape and are arranged parallel and in close proximity to each other.

5. System for measurement according to claim 4, characterized in that the second receiving electrode (R(A−B)) is preferably arranged within the receiving plate such that the projection of said second receiving electrode on the transmitting plate is included within a perimeter including the contours of the second transmitting electrode (TA) and of the receiving electrode of inverse polarity (TB).

6. System for measurement according to claim 4, characterized in that the two first transmitting electrodes (T1, T2) and the second transmitting electrode (TA) are electrically connected and excited by a same high-frequency modulated excitation signal, and in that the two first receiving electrodes (R1, R2) are electrically connected.

7. System for measurement according to claim 4, characterized in that the processing means comprises means for performing the analogue calculation:
1/(C1+C2)
where C1 and C2 are the capacitances respectively constituted by the first transmitting electrodes (T1, T2) and the first receiving electrodes (R1, R2).

8. System for measurement according to claim 7, characterized in that the processing means comprise means of performing the analogue calculation:
CA−CB/(C1+C2)
where C1 and C2 are the capacitances respectively constituted by the first transmitting electrodes (T1, T2) and the first receiving electrodes (R1, R2) and where CA−CB represents the capacitance constituted by, on the one hand, the second transmitting electrode (TA) and the transmitting electrode of inverse polarity (TB) and, on the other hand, the second receiving electrode (R(A−B)).

9. System for measurement according to claim 8, characterized in that the processing means comprise a preamplifier stage (20) for pre-amplifying the measurement signals respectively taken from the second receiving electrode (R(A−B)) and from the two first, electrically connected, receiving electrodes (R1, R2), upstream of the analogue calculation means (21).

10. System for measurement according to claim 9, characterized in that the analogue calculation means are designed to process analogue offset information supplied by digital-to-analogue conversion means connected to digital control means.

11. System for measurement according to claim 9, characterized in that the analogue calculation means comprise means of demodulating the signals resulting from the analogue calculations.

12. System for measurement according to claim 1, characterized in that the transmitting and receiving plates respectively comprise supports made of flexible material.

13. system for measurement according to claim 12, characterized in that the flexible material constituting the supports is polyamide.

14. System for measurement according to claim 12, characterized in that the flexible material constituting the supports is made from a flexible printed circuit.

15. System for measurement according to claim 12, in which at least said first and second objects comprise a mirror, characterized in that at least one of the supports made of flexible material is glued to said mirror.

16. System (S′) for measurement according to claim 1, characterized in that the processing means (500) comprise a first charge amplifier (501) whose input is connected to the third receiving electrode R(A−B) and to the output of a first modulator (511) connected as a multiplier, and a second charge amplifier (502) whose input is connected to the first and second receiving electrodes (R1, R2) and to the output of a second modulator (512) connected as a divider, the respective outputs of said first and second charge amplifiers (501, 502) being respectively connected as input to a first and to a second synchronous demodulator (515, 516) controlled by oscillator means, the respective outputs of said first and second synchronous demodulators (515, 516) being applied as input to a first and to a second integrator (517, 518) respectively, supplying a first analogue signal (Voz) representing the quantity
$$K [ \frac{CA - CB}{C1 + C2} \pm k0 ]$$
and a second analogue signal (Voy) representing the quantity
$$k [ \frac{1}{C1 + C2} ] .$$

17. System (S′) for measurement according to claim 16, characterized in that the processing means (500) further comprise a first and a second high-frequency amplifier (505, 504) respectively arranged, on the one hand, between the outputs of the first and second charge amplifiers (501, 502) and, on the other hand, between the inputs of the first and second synchronous demodulators (515, 516).

18. Application of the system for measurement according to claim 1, for measuring the relative position between two adjacent mirror segments.

19. Application according to claim 18, in which the transmitting and receiving plates respectively are fixed to facing lateral edges of two adjacent mirror segments, in close proximity to the active surfaces of said mirror segments.

20. Application according to claim 19, in which the non-contact system for measurement according to one of claims 1 to 11 is used for controlling the position (Tilt, Tip, piston and Global Radius of Curvature (GROC) of the mirror) of mirror segments.

21. Application according to claim 18, in the field of large-sized telescopes with segmented mirrors.

22. Method for non-contact measurement of a relative displacement or of a relative position of a first object with respect to a second object, used in a system according to one of the preceding claims, comprising:
an application of high-frequency excitation signals to transmitting electrodes arranged on a transmitting plate fixed to said first object,
a taking of high-frequency modulated measurement signals from receiving electrodes arranged on a receiving plate fixed to said second object, at least a part of said electrodes, transmitting and receiving respectively, being substantially facing each other when the transmitting and receiving plates respectively are substantially aligned,
a processing of said measurement signals thus taken in such a way as to provide signals representing the relative displacement or the relative position of said first object with respect to said second object,
characterized in that this processing comprises an analogue calculation (i) of a first signal representing the inverse of a first capacitance and (ii) of a second signal representing the ratio of a second capacitance to said first capacitance, said first capacitance being constituted by at least one of said transmitting electrodes and at least one of said receiving electrodes in such a way as to vary as a function of the distance separating the transmitting and receiving plates respectively, and said second capacitance being constituted by at least another of said transmitting electrodes and at least another of said receiving electrodes in such a way as to vary as a function of the relative misalignment of said plates.

23. Method for measurement according to claim 22, in which the transmitting electrodes comprise two first transmitting electrodes (T1, T2), a second transmitting electrode (TA) and a transmitting electrode (TB) with a polarity that is the inverse of that of said second transmitting electrode (TA), the receiving electrodes comprise two first receiving electrodes (R1, R2) and a second receiving electrode (R(A−B)) facing at least a part of said second transmitting electrode (TA) and at least a second part of said transmitting electrode (TB) of inverse polarity, said first transmitting electrodes and said second transmitting electrode being electrically connected and excited by the same high-frequency modulated excitation signal, and said first receiving electrodes being electrically connected in order to constitute (i) a capacitance C1+C2 corresponding to the putting in parallel of two capacitances (C1, C2) respectively constituted by each first transmitting electrode (T1, T2) and each corresponding first receiving electrode (R1, R2).

24. Method for measurement according to claim 23, characterized in that the analogue calculation comprises a calculation of the quantity:
1/(C1+C2)
where C1 and C2 are the capacitances respectively constituted by the first transmitting electrodes (T1, T2) and the first receiving electrodes (R1, R2).

25. Method for measurement according to claim 23, characterized in that the analogue calculation comprises a calculation of the quantity:
CA−CB/(C1+C2)
where C1 and C2 are the capacitances respectively constituted by the first transmitting electrodes (T1, T2) and the first receiving electrodes (R1, R2) and where CA−CB represents the capacitance constituted by, on the one hand, the second transmitting electrode (TA) and the transmitting electrode of inverse polarity (TB) and, on the other hand, the second receiving electrode (R(A−B)).

26. Method according to claim 23, characterized in that it further comprises, prior to the analogue calculation, an ultra low noise pre-amplification of the measurement signals taken from the second receiving electrode (R(A−B)) and from the two first electrically connected receiving electrodes (R1, R2) respectively.
